(19) United States
(12) Patent Application Publication
(10) Pub. No.: US 2019/0194803 A1
(43) Pub. Date: Jun. 27, 2019

(54) SUSCEPTOR CLEANING METHOD

(71) Applicant: Tokyo Electron Limited, Tokyo (JP)

(72) Inventor: Hitoshi KATO, Iwate (JP)

(21) Appl. No.: 16/225,429

(22) Filed: Dec. 19, 2018

(30) Foreign Application Priority Data
Dec. 27, 2017 (JP) 2017-251954

(51) Int. Cl. C23C 16/44; C23C 16/34; C23C 16/40; C23C 16/56; C23C 16/458; C23C 16/52; H01L 21/687

(52) U.S. Cl. CPC C23C 16/4405; C23C 16/345; C23C 16/401; H01L 21/68757; C23C 16/4584; C23C 16/52; C23C 16/56

(57) ABSTRACT

A susceptor cleaning method for cleaning a susceptor in a processing chamber is provided. The susceptor cleaning method includes a pre-coating film forming step of placing the susceptor in the processing chamber and forming a pre-coating film on a surface of the susceptor; a deposited film forming step of placing a substrate on the susceptor having the pre-coating film formed thereon and performing a film forming process in the course of which a deposited film is formed on the susceptor; a crack generating step of generating cracks in the deposited film; a pre-coating film removing step of supplying a pre-coating film removing gas into the processing chamber, causing the pre-coating film removing gas to reach the pre-coating film through the cracks, and removing the pre-coating film; and a deposited film removing step of removing the deposited film.

### CROSS-REFERENCE TO RELATED APPLICATION

The present application is based on and claims priority to Japanese Patent Application No. 2017-251954 filed on Dec. 27, 2017, the entire contents of which are hereby incorporated by reference.

### BACKGROUND OF THE INVENTION

### 1. Field of the Invention

The present invention generally relates to a susceptor cleaning method that is implemented in a film forming apparatus.

### 2. Description of the Related Art

Methods for forming a thin film of silicon oxide (SiO₂) or the like using a film forming apparatus including a vacuum chamber that accommodates a susceptor, which is a rotating table for holding a plurality of substrates such as semiconductor wafers, are known. As a thin film is formed in a film forming process, deposits are formed on the surface of the susceptor, and particles are formed as a result of such deposits peeling off from the surface of the susceptor. In this respect, for example, a technique for performing a dry cleaning process is known that involves providing a cleaning gas nozzle in a film forming apparatus, and supplying a cleaning gas such as a fluorine-based gas from the cleaning gas nozzle to the susceptor after a film forming process has been performed a predetermined number of times (see, e.g., Japanese Unexamined Patent Publication No. 2015-142038).

When film forming processes are performed for forming an insulating film, a protective film, or the like on a substrate, a deposited film that adheres to the surface of the susceptor holding the substrate may not be sufficiently removed even when a cleaning gas such as a fluorine-based gas is supplied. For example, high-K films made of high-K materials, such as HfO, ZrO, AlO, and the like, cannot be easily removed with a cleaning gas. To remove such a deposited film, the susceptor has to be taken out of the film forming apparatus to perform a wet cleaning process that may involve immersing the susceptor in a cleaning solution, for example.

However, when a cleaning process using a cleaning solution is performed, although the deposited film may be removed, the susceptor may also be etched by the cleaning solution. As a result, the susceptor may be unsuitable for reuse and the service life of the susceptor may be shortened.

### SUMMARY OF THE INVENTION

An aspect of the present invention is directed to providing a susceptor cleaning method that enables reuse of a susceptor by preventing etching of the susceptor while cleaning the susceptor.

According to one embodiment of the present invention, a susceptor cleaning method for cleaning a susceptor in a processing chamber is provided. The susceptor cleaning method includes a pre-coating film forming step of placing the susceptor in the processing chamber and forming a pre-coating film on a surface of the susceptor; a deposited film forming step of placing a substrate on the susceptor having the pre-coating film formed thereon and performing a film forming process in the course of which a deposited film is formed on the susceptor; a crack generating step of generating cracks in the deposited film; a pre-coating film removing step of supplying a pre-coating film removing gas into the processing chamber, causing the pre-coating film removing gas to reach the pre-coating film through the cracks, and removing the pre-coating film; and a deposited film removing step of removing the deposited film.

### BRIEF DESCRIPTION OF THE DRAWINGS

FIG. 1 is a longitudinal cross-sectional view of a film forming apparatus to be subjected to a susceptor cleaning method according to an embodiment of the present invention;

FIG. 2 is a schematic perspective view of an internal structure of the film forming apparatus of FIG. 1;

FIG. 3 is a diagram showing a schematic plan view of the internal structure of the film forming apparatus of FIG. 1 and an internal configuration of a control unit;

FIGS. 4A and 4B are respectively example longitudinal cross-sectional views of a supply region and separation region of the film forming apparatus of FIG. 1;

FIGS. 5A and 5B are diagrams illustrating the size of the separation region;

FIG. 6 is another longitudinal cross-sectional view of the film forming apparatus of FIG. 1;

FIG. 7 is another longitudinal cross-sectional view of the film forming apparatus of FIG. 1;

FIG. 8 is a partial perspective view of the film forming apparatus of FIG. 1;

FIG. 9 is a flowchart of a susceptor cleaning method according to an embodiment of the present invention;

FIG. 10 is a diagram schematically showing a process flow of a susceptor cleaning method according to a first embodiment; and

FIG. 11 is a diagram schematically showing a process flow of a susceptor cleaning method according to a second embodiment.

### DESCRIPTION OF THE PREFERRED EMBODIMENTS

In the following, embodiments for implementing a susceptor cleaning method according to the present invention will be described with reference to the accompanying drawings. First, a film forming apparatus to be subjected to a susceptor cleaning method according to an embodiment of the present invention will be described. Then, the susceptor cleaning method that is implemented in the film forming apparatus will be described. Note that in the following description and the drawings, elements having substantially the same features are given the same reference numerals and overlapping descriptions will be omitted.

[Film Forming Apparatus]

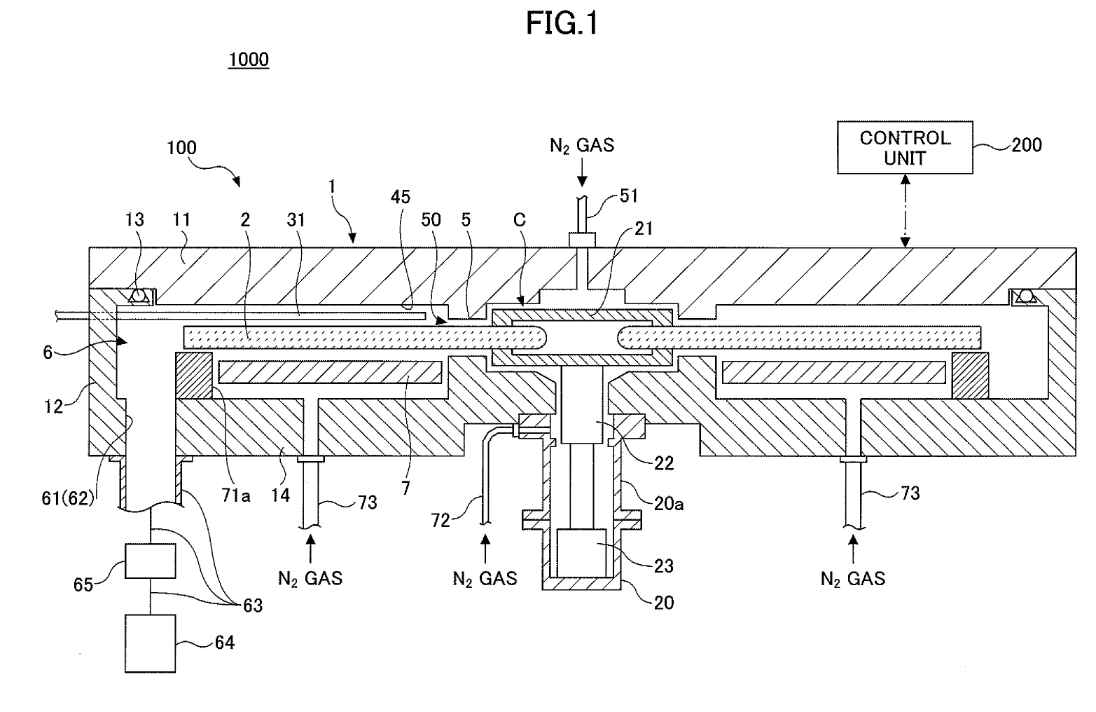

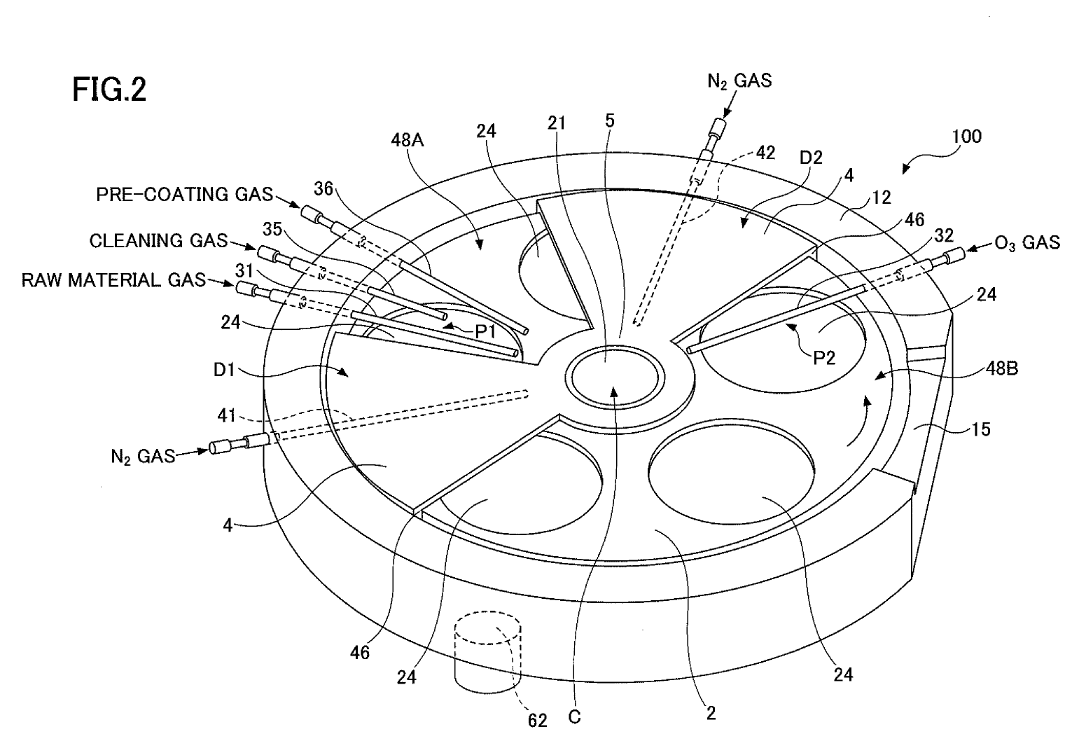

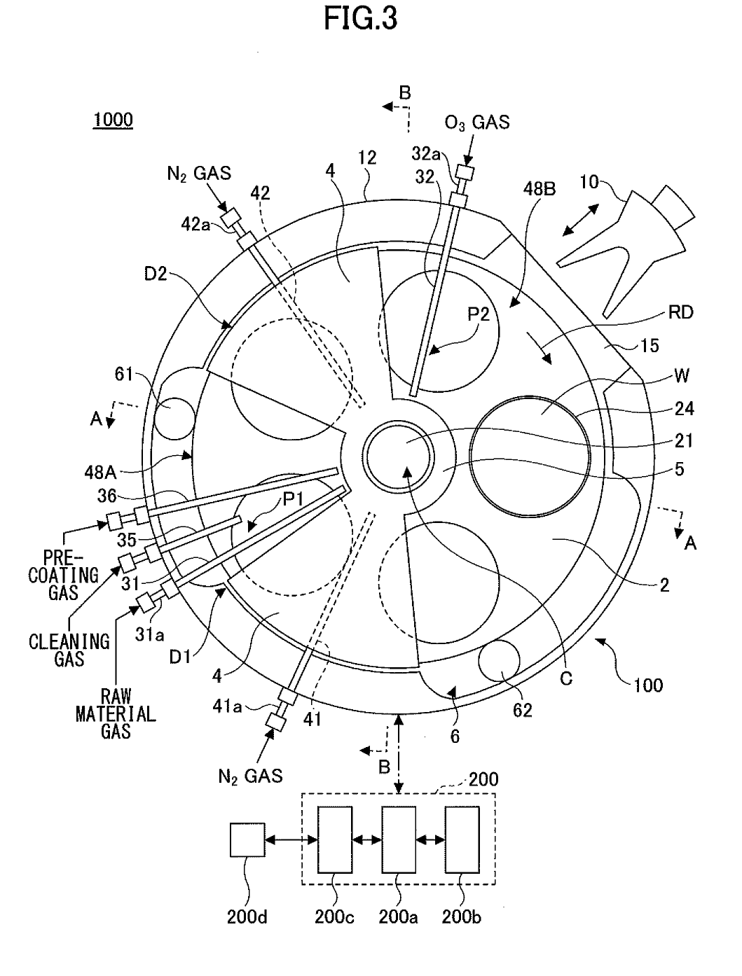

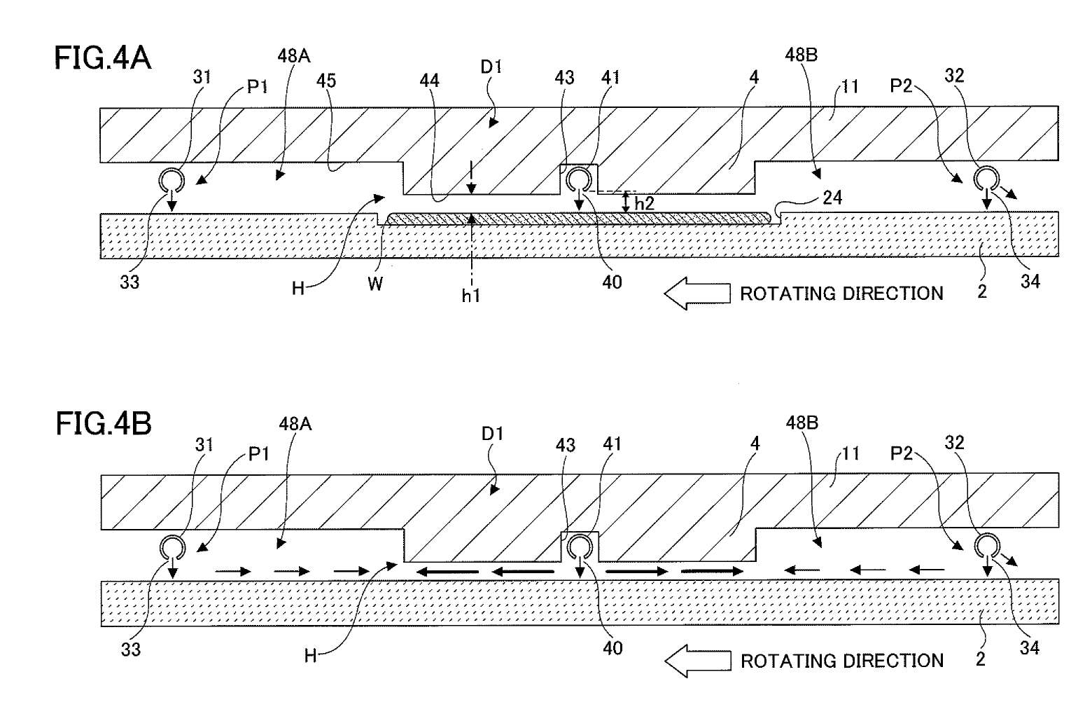

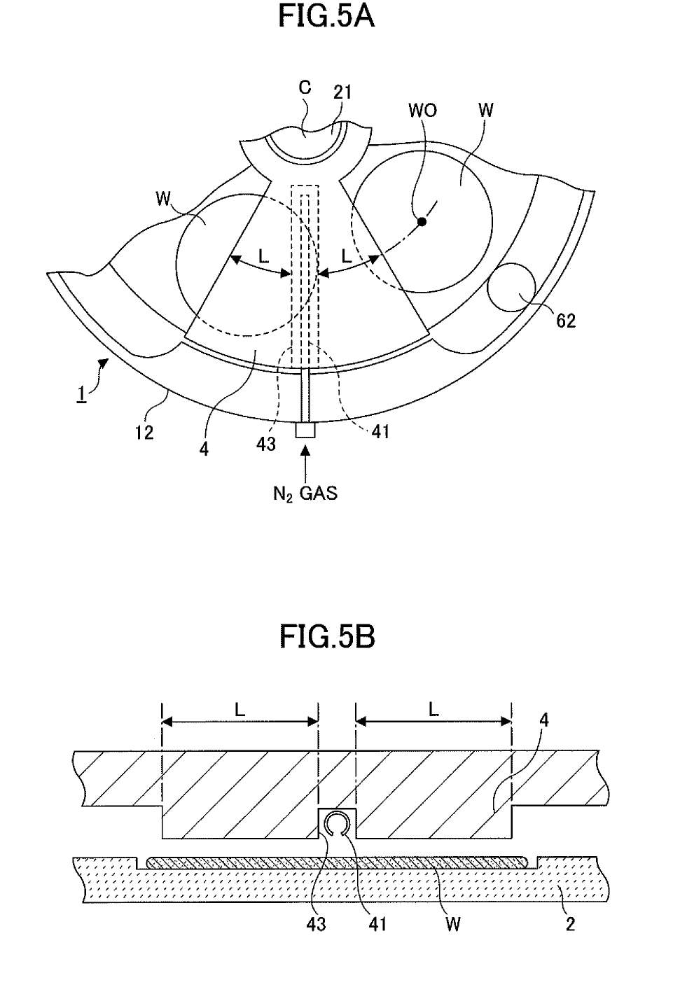

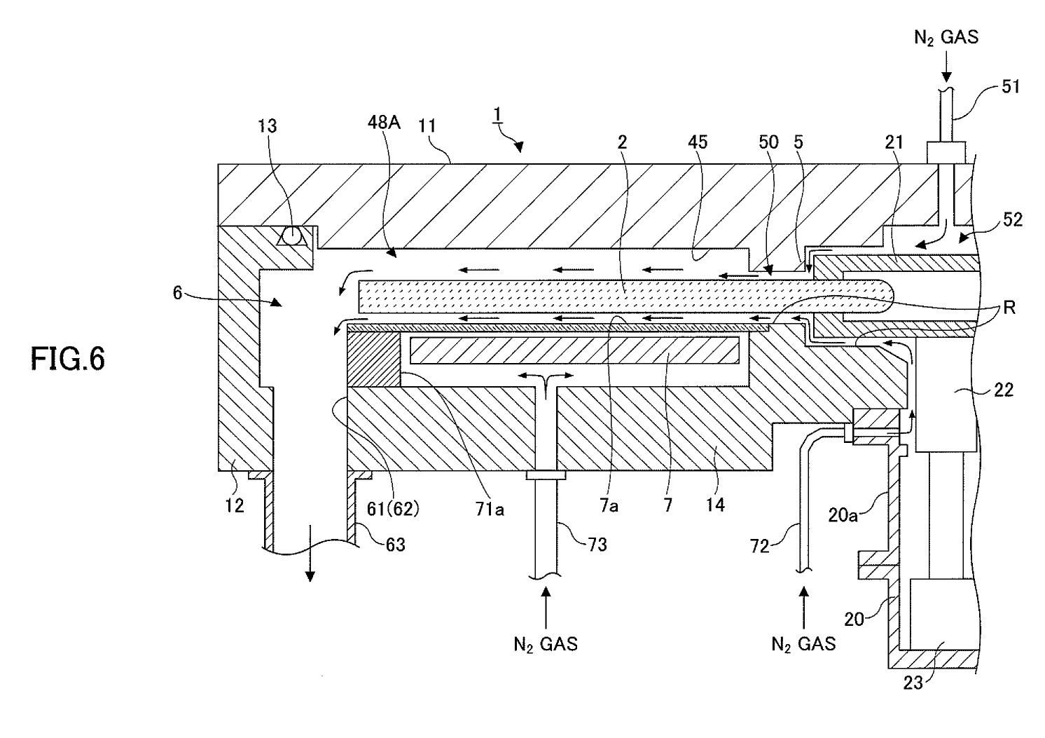

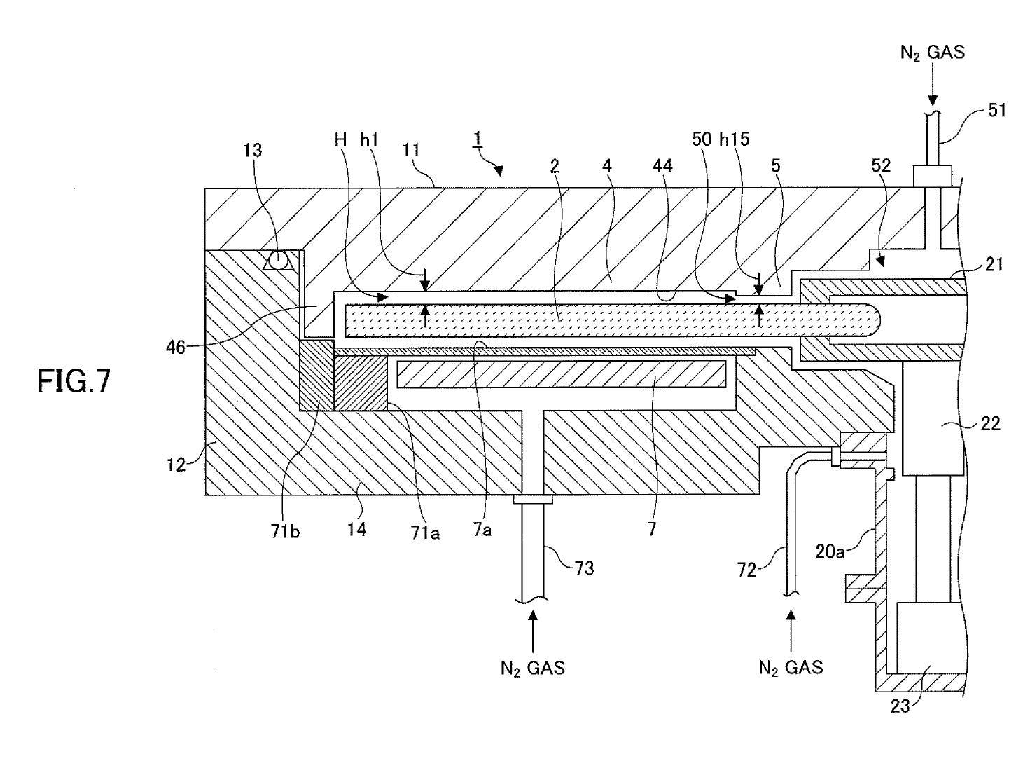

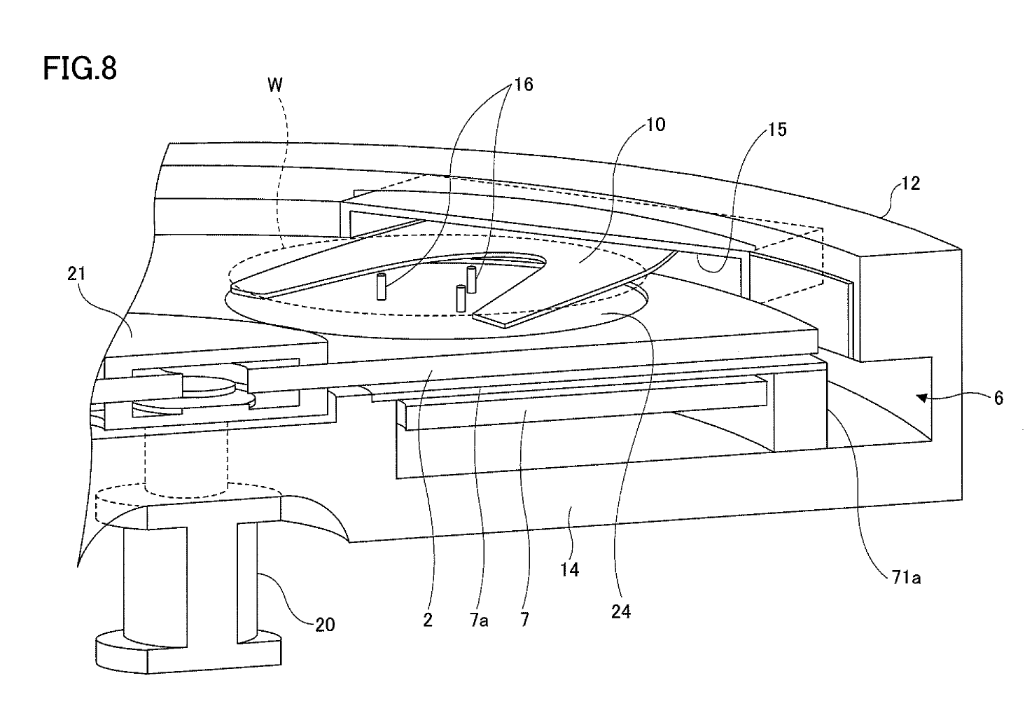

First, a film forming apparatus to be subjected to a susceptor cleaning method according to an embodiment of the present invention will be described. Although the susceptor cleaning method according to an embodiment of the present invention can be implemented in various film forming apparatuses, a film forming apparatus according to one embodiment that is suitable for implementing a susceptor cleaning method according to an embodiment of the present invention will be described below. FIG. 1 is a longitudinal cross-sectional view of a film forming apparatus to be subjected to a susceptor cleaning method according to an embodiment of the present invention. FIG. 2 is a schematic perspective view of an internal structure of the film forming apparatus of FIG. 1. FIG. 3 is a diagram showing a schematic plan view of the internal structure of the film forming apparatus of FIG. 1 and an internal configuration of a control unit. FIGS. 4A and 4B are longitudinal cross-sectional views of a supply region and a separation region in the film forming apparatus of FIG. 1. FIGS. 5A and 5B are diagrams illustrating the size of the separation region. FIGS. 6 and 7 are other longitudinal cross-sectional views of the film forming apparatus. FIG. 8 is a partial perspective view of the film forming apparatus of FIG. 1.

As shown in FIG. 1 (cross-sectional view across line A-A of FIG. 3) and FIG. 2, the film forming apparatus 1000 to be subjected to a susceptor cleaning method according to an embodiment of the present invention includes a processing chamber 100 and a control unit 200. The processing chamber 100 includes a flat vacuum chamber 1 having a substantially circular plane shape and a susceptor 2 having a rotation center coinciding with the center of the vacuum chamber 1. The control unit 200 controls the overall operation of the film forming apparatus 1000. The vacuum chamber 1 is a processing chamber for accommodating a wafer W, as an example of a substrate, and performing a film forming process on the surface of the wafer W. The vacuum chamber 1 is composed of a chamber body 12 and a top plate 11 that can be detached from the chamber body 12. The top plate 11 is attached to the chamber body 12 via a sealing member 13 such as an O-ring, for example, and in this way, the vacuum chamber 1 is hermetically sealed in an airtight manner. The top plate 11 and the chamber body 12 may be made of aluminum (Al), for example. Further, the susceptor 2 may be made of quartz, for example.

As shown in FIG. 1, the susceptor 2 is a disk-shaped rotating table having a circular opening at its center, and the susceptor 2 is held between a cylindrical core portion 21 that is arranged above and below the susceptor 2 near its center opening. The core portion 21 is fixed to an upper end of a rotating shaft 22 extending in the vertical direction. The rotating shaft 22 passes through a bottom portion 14 of the chamber body 12 and has a lower end attached to a driving unit 23 for rotating the rotating shaft 22 around a vertical axis. With such a configuration, the susceptor 2 can rotate around its center axis as the rotation center. The rotating shaft 22 and the driving unit 23 are accommodated in a cylindrical case body 20 that has an opening at an upper surface. The case body 20 is air-tightly attached to the bottom surface of the bottom portion 14 of the vacuum chamber 1 via a flange portion 20a provided on the upper surface of the case body 20, and in this way, the internal atmosphere of the case body 20 is isolated from the external atmosphere.

As shown in FIGS. 2 and 3, a plurality of recessed portions 24 (five in the illustrated example) having circular shapes in planar view that can accommodate wafers W are formed at equiangular intervals on the upper surface of the susceptor 2. Note, however, that in FIG. 3, only one recessed portion 24 has a wafer W accommodated therein.

FIG. 4A is a longitudinal cross-sectional view of the susceptor 2 with the wafer W placed in the recessed portion 24. As shown in FIG. 4A, the recessed portion 24 has a diameter (e.g., 4 mm) that is slightly larger than the diameter of the wafer W. Further, the depth of the recessed portion 24 is substantially equal to the thickness of the wafer W. By arranging the depth of the recessed portion 24 to be substantially equal to the thickness of the wafer W, when the wafer W is placed in the recessed portion 24, the surface of the wafer W will be at substantially the same height as the height of surface regions of the susceptor 2 other than the recessed portions 24 of the susceptor 2. If the height difference between the wafer W and the surface regions of the susceptor 2 other than the recessed portions 24 of the susceptor 2 is relatively large, the height difference may cause turbulence in the gas flow and influence the film thickness uniformity of the wafer W. In order to reduce such an influence, the surface of the wafer W and the surface regions of the susceptor 2 other than the recessed portions 24 of the susceptor 2 are arranged to be substantially the same height. Note that the expression “substantially the same height” as used herein refers a height difference of about 5 mm or less, for example, but the height difference is preferably as close to zero as possible within the allowable range of machining accuracy.

Referring to FIGS. 2 to 4B, two protruding portions 4 that are separated from one another are provided along the rotation direction of the susceptor 2 (e.g., arrow RD in FIG. 3). Note that in FIGS. 2 and 3, illustration of the top plate 11 is omitted for the sake of illustrating the interior of the vacuum chamber 1. As shown in FIGS. 4A and 4B, the protruding portion 4 is provided on the lower surface of the top plate 11. As can be appreciated from FIG. 3, the protruding portion 4 has a substantially fan-shaped planar shape with an apex portion of the substantially fan shape being positioned substantially at the center of the vacuum chamber 1 and a circular arc portion of the substantially fan shape being positioned along the inner peripheral wall of the chamber body 12. Further, as shown in FIG. 4A, a lower surface 44 (also referred to as “ceiling surface 44”) of the protruding portion 4 is arranged to be at height h1 from the surface of the susceptor 2 or the surface of the wafer W placed in the recessed portion 24 of the susceptor 2.

As shown in FIGS. 3 to 4B, each protruding portion 4 has a groove portion 43 extending in the radial direction to divide the protruding portion 4 into two parts, and the groove portion 43 accommodates a separation gas nozzle 41 (42). Note that although the groove portion 43 is arranged to divide the protruding portion 4 into two equal parts in the present embodiment, the groove portion 43 may also be arranged to divide the protruding portion 4 so that the upstream side of the protruding portion 4 in the rotating direction of the susceptor 2 is larger than the downstream side, for example. As shown in FIG. 3, the separation gas nozzle 41 (42) is introduced into the vacuum chamber 1 from a peripheral wall portion of the chamber body 12, and a gas introduction port 41a (42a) corresponding to a base end portion of the separation gas nozzle 41 (42) is arranged at an outer peripheral wall of the chamber body 12 to support the separation gas nozzle 41 (42).

The separation gas nozzle 41 (42) is connected to a separation gas supply source (not shown). Example gases that may be used as the separation gas include, nitrogen (N₂) gas, an inert gas, and the like, but the type of gas used is not particularly limited as long as it does not affect the film formation. In the present embodiment, N₂ gas is used as the separation gas. The separation gas nozzle 41 (42) also has discharge holes 40 (FIGS. 4A and 4B) for discharging N₂ gas toward the surface of the susceptor 2. The discharge holes 40 are arranged at predetermined intervals along the length direction of the separation gas nozzle 41 (42). In the present embodiment, the discharge holes 40 have a diameter of about 0.5 mm and are arranged at intervals of about 10 mm along the length direction of the separation gas nozzle 41 (42).

With the above configuration, the separation gas nozzle 41 and the corresponding protruding portion 4 provide a separation region D1 that defines a separation space H (FIGS. 4A and 4B). Similarly, the separation gas nozzle 42 and the corresponding protruding portion 4 provide a separation region D2 that defines a separation space H. Also, a first region 48A (first supply region) is formed downstream of the separation region D1 in the rotating direction of the susceptor 2. The first region 48A is substantially surrounded by the peripheral edges of the separation regions D1 and D2, the surface of the susceptor 2, a lower surface 45 of the top plate 11 (hereinafter referred to as “ceiling surface 45”), and the inner peripheral wall of the chamber body 12. Further, a second region 48B (second supply region) is formed upstream of the separation region D1 in the rotating direction of the susceptor 2. The second region 48B is substantially surrounded by the peripheral edges of the separation regions D1 and D2, the surface of the susceptor 2, the ceiling surface 45, and the inner peripheral wall of the chamber body 12. When N₂ gas is discharged from the separation gas nozzles 41 and 42 into the separation regions D1 and D2, the pressures at the separation spaces H of the separation regions D1 and D2 become relatively high such that the N₂ gas flows from the separation spaces H toward the first region 48A and the second region 48B. That is, the protruding portions 4 in the separation regions D1 and D2 guide the N₂ gas supplied from the separation gas nozzles 41 and 42 toward the first region 48A and the second region 48B.

Also, as shown in FIGS. 2 and 3, a raw material gas nozzle 31 and a pre-coating gas nozzle 36 are introduced into the first region 48A from the peripheral wall of the chamber body 12 to extend in the radial direction of the susceptor 2, and an oxidizing gas nozzle 32 for supplying an oxidizing gas such as ozone is introduced into the second region 48B from the peripheral wall of the chamber body 12 to extend in the radial direction of the susceptor 2. Like the separation gas nozzles 41 and 42, the raw material gas nozzle 31 and the oxidizing gas nozzle 32 are respectively supported by gas introduction ports 31a and 32a corresponding to base end portions of the raw material gas nozzle 31 and the oxidizing gas nozzle 32 arranged at the outer peripheral wall of the chamber body 12. Note that the oxidizing gas is not limited to ozone, and for example, oxygen may also be used as the oxidizing gas. In the present embodiment, the raw material gas nozzle 31 and the pre-coating gas nozzle 36 are provided as separate gas nozzles under the premise that a high-K film (high dielectric film) is formed on the surface of the wafer W in a film forming process so that a reaction gas that is different from an organometallic gas or the like that is used for forming the high-K film is used as the pre-coating gas in the susceptor cleaning method according to the present embodiment. However, in other embodiments, for example, the pre-coating gas nozzle 36 may be eliminated and the raw material gas nozzle 31 may be configured to communicate with a raw material gas supply source and a pre-coating gas supply source via a switch valve, and the switch valve may be used to switch between supplying the raw material gas and supplying the pre-coating gas to the susceptor 2.

The raw material gas nozzle 31 and the oxidizing gas nozzle 32 respectively have a plurality of discharge holes 33 and 34 for discharging the corresponding reaction gases toward the upper surface of the susceptor 2 (the surface having the recessed portions 24 for accommodating the wafers W) (FIGS. 4A and 4B). Similarly, the pre-coating gas nozzle 36 has a plurality of discharge holes (not shown) for discharging the pre-coating gas toward the upper surface of the susceptor 2. In the present embodiment, the discharge holes 33 and 34 have a diameter of about 0.5 mm and are arranged at intervals of about 10 mm along the length direction of the raw material gas nozzle 31 and the oxidizing gas nozzle 32. The discharge holes formed in the pre-coating gas nozzle 36 also have the same diameter and are arranged at the same intervals.

The raw material gas nozzle 31 is connected to a raw material gas supply source (not shown), the pre-coating gas nozzle 36 is connected to a pre-coating gas supply source (not shown), and the oxidizing gas nozzle 32 is connected to an ozone gas supply source (not shown). Although various gases may be used as the raw material gas, in the present embodiment, it is assumed that an organometallic gas or an organic metalloid gas is used, and the raw material gas to be used is selected according to the type of insulating film or protective film to be formed. For example, the organometallic gas may be an organometallic gas used for forming a high-K film. In this case, a gas such as tri(dimethylamino)cyclopentadienylzirconium (C₁₁H₂₃N₃Zr) may be used, for example. In the following, an example case where an organometallic gas for forming a high-K film is used will be described. Also, in the following description, a region below the raw material gas nozzle 31 where the organometallic gas is adsorbed by the wafer W is referred to as “processing region P1”, and a region below the oxidizing gas nozzle 32 where O₃ gas is to react with (oxidize) the organometallic gas adsorbed to the wafer W is referred to as “processing region P2”.

Also, a cleaning gas nozzle 35 is provided in the first region 48A. The cleaning gas nozzle 35 is not used during a film forming process but is used when performing a cleaning method for dry cleaning the interior of the vacuum chamber 1 including the susceptor 2 after the film forming process has been continually performed for some time and it has been determined that a deposited film formed by oxide films that have been deposited on the surface of the susceptor 2 and inside the vacuum chamber 1 should be removed. In one aspect of the susceptor cleaning method according to an embodiment the present invention, a pre-coating film is formed on the surface of the susceptor 2 before performing the film forming process, and after the film forming process, a fluorine-based gas such as ClF₃ gas is supplied from the cleaning gas nozzle 35. Note that the susceptor cleaning method according to an embodiment the present invention will be described in detail below.

Referring back to FIG. 4A, the ceiling surface 44 at the separation region D1 is arranged to be a low ceiling surface (although not shown, a similarly low ceiling surface is provided at the separation region D2). On the other hand, ceiling surfaces 45 at the first region 48A and the second region 48B are higher than the ceiling surface 44. Therefore, the volumes of the first region 48A and the second region 48B are larger than the volumes of the separation spaces H in the separation regions D1 and D2. As will be described below, the vacuum chamber 1 according to the present embodiment is provided with exhaust ports 61 and 62 for exhausting the first region 48A and the second region 48B, respectively. By providing these exhaust ports 61 and 62, the pressures at the first region 48A and the second region 48B may be maintained at lower pressures as compared with the pressures at the separation spaces H of the separation regions D1 and D2. In this case, because the pressures at the separation spaces H of the separation regions D1 and D2 are higher, the organometallic gas discharged from the raw material gas nozzle 31 in the first region 48A cannot pass through the separation space H and reach the second region 48B. Similarly, because the pressures at the separation spaces H of the separation regions D1 and D2 are higher, O₃ gas discharged from the oxidizing gas nozzle 32 in the second region 48B cannot pass through the separation space H and reach the first region 48A. In this way, the two reaction gases (i.e., the organometallic gas and the O₃ gas) can be separated by the separation regions D1 and D2 such that the reaction gases will hardly be mixed together in the gas phase inside the vacuum chamber 1.

Although the height h1 of the low ceiling surface 44 (FIG. 4A) measured from the upper surface of the susceptor 2 depends on the amount of N₂ gas supplied from the separation gas nozzle 41 (42), the height h1 is suitably adjusted so that the pressures at the separation spaces H of the separation regions D1 and D2 will be higher than the pressures at the first region 48A and the second region 48B. For example, the height h1 is preferably set to be in a range from 0.5 mm to 10 mm, and is more preferably set to be as low as possible. However, to avoid collision of the susceptor 2 against the ceiling surface 44 due to rotational blur of the susceptor 2, the height h1 is more preferably set to be in a range from about 3.5 mm to 6.5 mm within the above numerical range. Also, a height h2 (FIG. 4A) of the lower edge of the separation gas nozzle 42 (41) accommodated in the groove portion 43 of the protruding portion 4 from the surface of the susceptor 2 is preferably adjusted to be in a range from 0.5 mm to 4 mm for the same reasons.

Also, referring to FIGS. 5A and 5B, a length L of an arc corresponding to a path travelled by a wafer center WO across half the protruding portion 4 is preferably set to be about 1/10 to about 1/1 of the diameter of the wafer W, and more preferably at least about ⅙ of the diameter of the wafer W. By setting the length L of the arc to be within the above numerical range, the pressures at the separation spaces H of the separation regions D1 and D2 can be reliably maintained at desirably high pressures.

By arranging the separation regions D1 and D2 to have the above-described configuration, the organometallic gas and the O₃ gas can be more reliably separated even when the susceptor 2 rotates at a rotation speed about 240 rpm, for example.

Referring back to FIGS. 1 to 3, an annular protruding portion 5 surrounding the core portion 21 is provided on the ceiling surface 45 of the top plate 11. The protruding portion 5 faces a region of the susceptor 2 at the outer side of the core portion 21. In the present embodiment, as clearly shown in FIG. 7, a height h15 of a space 50 defined by the lower surface of the protruding portion 5 from the susceptor 2 is slightly lower than the height h1 of the space H. This is because the rotational blur around the center of the susceptor 2 is smaller than that at the periphery of the susceptor 2. Specifically, the height h15 may be set to be in a range from about 1.0 mm to 2.0 mm. Note that in other embodiments, the height h15 and the height h1 may be equal. Also, the protruding portion 5 and the protruding portion 4 may be integrally formed, or they may be separately formed. Note that FIGS. 2 and 3 are views of the interior of the vacuum chamber 1 with the top plate 11 being omitted while leaving the protruding portion 4 in the vacuum chamber 1.

As shown in FIG. 6, which is an enlarged partial view of about half of FIG. 1, a separation gas supply pipe 51 is connected to a center portion of the top plate 11 of the vacuum chamber 1, and such a configuration allows N₂ gas to be supplied to a space 52 between the top plate 11 and the core portion 21. By supplying the N₂ gas to the space 52, the pressure in the narrow space 50 between the protruding portion 5 and the susceptor 2 can be maintained at a higher pressure than the pressures at the first region 48A and the second region 48B. Thus, the organometallic gas discharged from the raw material gas nozzle 31 in the first region 48A can be prevented from reaching the second region 48B via the high-pressure space 50. Also, the O₃ gas discharged from the oxidizing gas nozzle 32 in the second region 48B can be prevented from reaching the first region 48A via the high-pressure space 50. In this way, the two reaction gases can be separated by the space 50 and can be substantially prevented from mixing in the gas phase in the vacuum chamber 1. That is, in the film forming apparatus according to the present embodiment, in order to separate the organometallic gas and the O₃ gas, a center region C that is maintained at a higher pressure than the pressures at first region 48A and the second region 48B is defined by the rotation center portion of the susceptor 2 and the vacuum chamber 1.

FIG. 7 is a partial cross-sectional view of about half the film forming apparatus 1000 across line B-B of FIG. 3. FIG. 7 shows the protruding portion 4 and the protruding portion 5 integrally formed with the protruding portion 4 at the separation region D1 (D2). As can be appreciated, the protruding portion 4 has a bent portion 46 bent into an L shape at its outer periphery. The bent portion 46 substantially fills the space (gap) between the susceptor 2 and the chamber body 12 and prevents the organometallic gas from the raw material gas nozzle 31 and the O₃ gas from the oxidizing gas nozzle 32 from passing through this gap and mixing with one another. The gap between the bent portion 46 and the chamber body 12 and the gap between the bent portion 46 and the susceptor 2 may be set up to be substantially equal to the height h1 of the ceiling surface 44 of the protruding portion 4 from the susceptor 2, for example. Also, by providing the bent portion 46, the N₂ gas from the separation gas nozzles 41 and 42 (FIG. 3) may be prevented from flowing toward the outer side of the susceptor 2. In this way, the flow of the N₂ gas from the separation regions D1 and D2 to the first region 48A and the second region 48B may be promoted. Further, by providing a block member 71b below the bent portion 46, the separation gas (N₂ gas) may be prevented from flowing toward a region below the susceptor 2.

Note that the gap between the bent portion 46 and the susceptor 2 is preferably set up to have the above distance (about the height h1 of the ceiling surface 44) in consideration of thermal expansion of the susceptor 2 that may occur when the susceptor 2 is heated by a heater unit as described below.

On the other hand, as shown in FIG. 3, at the first region 48A and the second region 48B, the inner peripheral wall of the chamber body 12 is recessed radially outward, and exhaust regions 6 are formed in the recessed regions. As shown in FIGS. 3 and 6, exhaust ports 61 and 62 may be arranged at the bottom of the exhaust regions 6, for example. The exhaust ports 61 and 62 may be connected to a common vacuum pump 64 (see FIG. 1) corresponding to a vacuum exhaust device via exhaust pipes 63, for example. With such a configuration, gas may be evacuated mainly from the first region 48A and the second region 48B so that the pressures at the first region 48A and the second region 48B may be arranged be lower than the pressures at the separation spaces H of the separation regions D1 and D2 as described above. Note that although the exhaust regions 6 are provided at the regions where the inner peripheral wall of the chamber body 12 are recessed outward in FIG. 3, the exhaust regions do not necessarily have to have such configuration, and various other configurations are possible for providing the exhaust ports 61 and 62 at the bottom of the exhaust regions.

Also, in FIG. 3, the exhaust port 61 for the first region 48A is positioned below the raw material gas nozzle 31 at the outer side (the exhaust region 6) of the susceptor 2. In this way, the organometallic gas from the raw material gas nozzle 31 can flow along the upper surface of the susceptor 2 toward the exhaust port 61 in the longitudinal direction of the raw material gas nozzle 31.

Referring back to FIG. 1, a pressure regulator 65 is provided in the exhaust pipe 63, and in this way, the pressure in the vacuum chamber 1 can be adjusted. Note that in some embodiments, a plurality of pressure regulators 65 may be provided for the respective exhaust ports 61 and 62. Also, note that the exhaust ports 61 and 62 are not limited to being provided at the bottom portion of the exhaust regions 6 (the bottom portion 14 of the vacuum chamber 1), but may alternatively be provided at peripheral wall portions of the chamber body 12 of the vacuum chamber 1, for example. Further, the exhaust ports 61 and 62 may be provided on portions of the top plate 11 in the exhaust regions 6, for example. However, when the exhaust ports 61 and 62 are provided on the top plate 11, the gas in the vacuum chamber 1 will flow upward, and as a result, particles in the vacuum chamber 1 may be blown up to cause contamination of the wafer W. As such, the exhaust ports 61 and 62 are preferably provided at the bottom portions of the exhaust regions 6 as shown in FIGS. 3 and 6, or at peripheral wall portions of the chamber body 12. Further, by providing the exhaust ports 61 and 62 at the bottom portions of the exhaust regions 6, the exhaust pipe 63, the pressure regulator 65, and the vacuum pump 64 can be installed below the vacuum chamber 1 so that the footprint of the film forming apparatus 1000 can be reduced.

As shown in FIGS. 1 and 6 to 8, an annular heater unit 7 is provided in the space between the susceptor 2 and the bottom portion 14 of the chamber body 12, and in this way, the susceptor 2 can be heated to a predetermined temperature, and if a wafer W is placed on the susceptor 2, the wafer W may also be heated to the predetermined temperature via the susceptor 2. Also, by providing a block member 71a surrounding the heater unit 7 below the susceptor 2 around the outer periphery of the susceptor 2, the space where the heater unit 7 is placed can be separated from a region outside the heater unit 7. Also, a slight gap is formed between the upper surface of the block member 71a and the lower surface of the susceptor 2 in order to prevent gas from entering the inner side of the block member 71a. The region where the heater unit 7 is accommodated is connected to a plurality of purge gas supply pipes 73 for purging this region. The plurality of purge gas supply pipes 73 penetrate through the bottom portion of the chamber body 12 at predetermined angular intervals to be connected to the region where the heater unit 7 is accommodated. Note that a protective plate 7a for protecting the heater unit 7 is provided above the heater unit 7. The protective plate 7a is supported by the block member 71a and a raised portion R (described below). In this way, even when the organometallic gas or the O₃ gas enters the space where the heater unit 7 is provided, the heater unit 7 can be protected from these reaction gases. The protective plate 7a is preferably made of quartz, for example.

As shown in FIG. 6, the bottom portion 14 of the chamber body 12 has a raised portion R arranged at the inner side of the annular heater unit 7. The upper surface of the raised portion R is arranged close to the susceptor 2 and the core portion 21 such that there are only small gaps between the upper surface of the raised portion R and the lower surface of the susceptor 2 and between the upper surface of the raised portion R and the lower surface of the core portion 21. Also, the bottom portion 14 has a center hole through which the rotating shaft 22 passes. The inner diameter of the center hole is slightly larger than the diameter of the rotating shaft 22 to thereby provide a gap that communicates with the interior of the case body 20 via a flange portion 20a. A purge gas supply pipe 72 is connected to the upper portion of the flange portion 20a.

With such a configuration, as shown in FIG. 6, N₂ gas from the purge gas supply pipe 72 may flow into the space below the susceptor 2 via the gap between the rotating shaft 22 and the center hole of the bottom portion 14, the gap between the core portion 21 and the raised portion R of the bottom portion 14, and the gap between the raised portion R of the bottom portion 14 and the lower surface of the susceptor 2. Also, N₂ gas from the purge gas supply pipes 73 may flow into the space below the heater unit 7. Then, the N₂ gas supplied from the purge gas supply pipes 72 and 73 flows into the exhaust port 61 through the gap between the block member 71a and the lower surface of the susceptor 2. The N₂ gas flowing in this manner acts as a separation gas for preventing the organometallic gas (or O₃ gas) from circulating in the space below the susceptor 2 and mixing with the O₃ gas (or organometallic gas).

As shown in FIGS. 2, 3 and 8, a transfer port 15 is formed at a peripheral wall portion of the chamber body 12. The wafer W can be transferred into the vacuum chamber 1 by a transfer arm 10 through the transfer port 15 or transferred out of the vacuum chamber 1 through the transfer port 15. A gate valve (not shown) is provided at the transfer port 15, and in this way, the transfer port 15 can be opened and closed. Three through holes (not shown) are formed at the bottom of the recessed portion 24 so that three lift pins 16 (see FIG. 8) can move up and down through these through holes. The lift pins 16 support the rear surface of the wafer W to raise and lower the wafer W, and in this way, the wafer W can be passed to and from the transfer arm 10.

Also, as shown in FIG. 3, the film forming apparatus 1000 according to the present embodiment includes a control unit 200 for controlling the operation of the entire apparatus. The control unit 200 includes a process controller 200a configured by a computer, a user interface unit 200b, and a memory device 200c, for example. The user interface unit 200b may include, for example, a display for displaying the operation status of the film forming apparatus and an input device, such as a keyboard or a touch panel, to be operated by an operator of the film forming apparatus to select a process recipe or a process manager to change parameters of the process recipe (not shown).

The control unit 200 also performs control for executing a susceptor cleaning method, which will be described below.

The memory device 200c stores a control program for causing the process controller 200a to execute various processes, process recipes, parameters for various processes, and the like. Also, the programs stored in the memory device include, for example, a program describing a set of steps for executing a susceptor cleaning method (described below). These control programs and process recipes are read and executed by the process controller 200a in accordance with an instruction from the user interface unit 200b. Further, these programs may be stored in a computer readable storage medium 200d and installed in the memory device 200c via a corresponding input/output device (not shown). The computer-readable storage medium 200d may be a hard disk, a CD, a CD-R/RW, a DVD-R/RW, a flexible disk, a semiconductor memory, or the like. Further, the program may be downloaded to the memory device 200c via a communication line, for example.

### Susceptor Cleaning Method According to First Embodiment

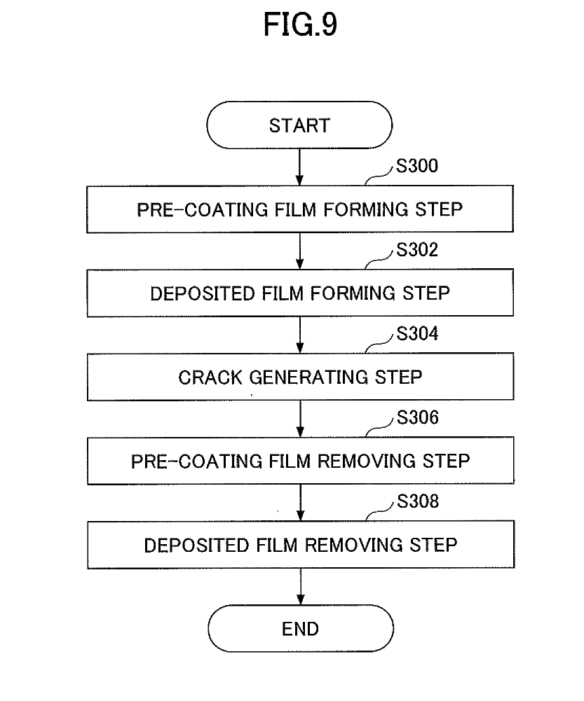

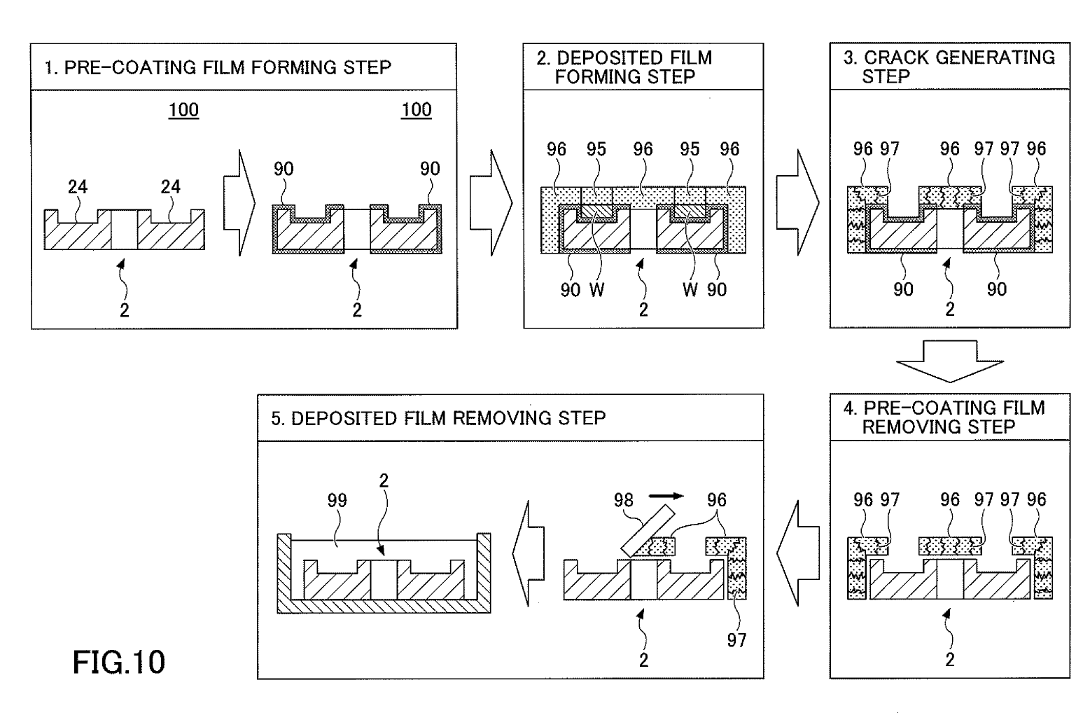

In the following, a susceptor cleaning method according to a first embodiment of the present invention will be described with reference to FIGS. 9 and 10. FIG. 9 is a flowchart of the susceptor cleaning method according to the first embodiment, and FIG. 10 is a diagram schematically illustrating the process flow of the susceptor cleaning method according to the first embodiment.

As shown in FIGS. 9 and 10, in the susceptor cleaning method according to the first embodiment, first, the susceptor 2 that does not have a wafer W placed thereon is set inside the processing chamber 100, and a pre-coating film forming step of forming a pre-coating film 90 on the surface of the susceptor 2 is executed (step S300).

In the pre-coating film forming step, a method substantially similar to a method of forming a silicon oxide film (SiO₂ film) on the surface of a wafer W is used to form a silicon oxide film on the surface of the susceptor 2 instead of the surface of a wafer W.

The internal atmosphere of the processing chamber 100 is set to a vacuum atmosphere, the heater unit 7 is operated to heat the susceptor 2, and the heated susceptor 2 is rotated at a predetermined rotation speed. Then, N₂ gas as the separation gas is supplied from the separation gas nozzles 41 and 42 to the rotating susceptor 2, a pre-coating gas is supplied from the pre-coating gas nozzle 36 to the rotating susceptor 2, and ozone (O₃) gas as the oxidizing gas is supplied from the oxidizing gas nozzle 32 to the rotating susceptor 2. These plural types of gases are supplied at the same time so that the reaction gases and the separation gas are simultaneously supplied to the susceptor 2.

Note that a silicon-containing gas is used as the pre-coating gas. Specific examples of silicon-containing gases that may be used as the pre-coating gas include aminosilane-based gases, such as 3DMAS tris(dimethylamino)silane (3DMAS, Si(N(CH₃)₂)₃H), tetrakis(dimethylamino)silane (4DMAS, Si(N(CH₃)₂)₄), tetrachlorosilane (TCS, siCl₄), dichlorosilane (DCS SiH₂Cl₂), monosilane (SiH₄), hexachlorodisilane (HCD, Si₂Cl₆), and the like.

As described above, a silicon-containing gas is used as the pre-coating gas, and a silicon-containing gas is also supplied from the raw material gas nozzle 31. As such, in the present embodiment, the pre-coating gas nozzle 36 does not necessarily have to be used and the raw material gas nozzle 31 may be used to supply the pre-coating gas, for example.

That is, in a manner similar to the method of forming a silicon oxide film on the surface of a wafer W, ALD (Atomic Layer Deposition) is implemented to sequentially cause adsorption of the silicon-containing gas onto the surface of the susceptor 2 and oxidization of the silicon-containing gas adsorbed on the surface of the susceptor 2 multiple times while rotating the susceptor 2.

By implementing such film forming method, a pre-coating film 90 made of a silicon oxide film may be formed on the surface of the susceptor 2. For example, the pre-coating film 90 may be made of a silicon oxide film having a thickness of about 300 nm. Note that the oxidizing gas corresponding to a reaction gas is not limited to ozone gas and may also be oxygen gas, for example.

As described above, in the present embodiment, a high-K film is formed on the surface of the wafer W, but the pre-coating film formed in the pre-coating film forming step is a film having an etch rate (or etching selectivity) that is different from the etch rate (or etching selectivity) of the insulating film or protective film that is formed in the film forming process (a high-K film corresponding to an insulating film in the present embodiment). For example, a high-K film made of HfO, ZrO, AlO or the like and a SiO₂ film have substantially different etch rates; the etch rate of the SiO₂ film is substantially higher than the etch rate of the high-K film.

As described above, in the susceptor cleaning method according to the first embodiment, the pre-coating film formed in the pre-coating film forming step and the film formed on the wafer surface (and the deposited film formed on the surface of the susceptor 2) in the film forming process are respectively arranged to be different types of films having different etch rates. More specifically, the pre-coating film 90 that is formed on the surface of the susceptor 2 in the pre-coating film forming step is arranged to be a film having a higher etch rate than the etch rate of the film formed on the wafer surface in the film forming process. Thus, in the case where a high-K film is formed in the film forming process as in the present embodiment, a film that has a higher etch rate than the high-K film such as a silicon nitride film may also be formed as the pre-coating film, for example.

In the case of forming a pre-coating film made of a silicon nitride film, for example, the same silicon-containing gas as described above may be discharged from the pre-coating gas nozzle 36, and the oxidizing gas nozzle 32 may be used as a nitriding gas nozzle for discharging a nitrogen-containing gas, such as NH₃ gas, as a reaction gas to thereby form a pre-coating film made of a silicon nitride film on the surface of the susceptor 2.

After forming the pre-coating film 90 made of a silicon oxide film on the surface of the susceptor 2 in the processing chamber 100, a wafer W as a substrate to be processed is loaded into the processing chamber 100 via the transfer port 15 of the processing chamber 100, and the wafer W is placed on the susceptor 2. Then, the internal atmosphere of the processing chamber 100 is set to a vacuum atmosphere, the heater unit 7 is operated to heat the susceptor 2 having the wafer W placed thereon, the susceptor 2 is rotated at a predetermined rotation speed, N₂ gas as the separation gas is supplied from the separation gas nozzles 41 and 42, and an organometallic gas or the like as the raw material gas is supplied from the raw material gas nozzle 31.

The organometallic gas that is used as the raw material gas may be a gas such as tri(dimethylamino)cyclopentadienylzirconium (C₁₁H₂₃N₃Zr), for example. Other example gases that may be used as the raw material gas include various organometallic gases generated by vaporizing an organometallic compound containing a metal such as aluminum, hafnium, titanium, or the like, or a semimetal such as silane, for example. By supplying ozone gas from the oxidizing gas nozzle 32 and causing the organometallic gas to react with the oxidizing gas and undergo oxidization, a high-K film 95 is formed. Note that the high-K film 95 is formed under a relatively low temperature atmosphere of about 300° C.

Specifically, ALD (atomic layer deposition) is implemented to sequentially cause adsorption of the organometallic gas to the surfaces of the wafer W and the susceptor 2 and oxidation of the organometallic gas adsorbed to the surfaces of the wafer W and the susceptor 2 multiple times while rotating the susceptor 2. By implementing such a film forming method, a high-K film 95 having a predetermined thickness is formed on the surface of the wafer W, and a deposited film 96 made of the high-K film corresponding to a cleaning target is formed on the surface regions of the susceptor 2 other than the recessed portions 24 accommodating the wafer W (step S302: deposited film forming step).

At the point where the high-K film 95 having a film thickness of about several nanometers (nm) has been formed on the surface of the wafer W, the wafer W is unloaded from the processing chamber 100, a different wafer W is loaded into the processing chamber 100 and placed on the susceptor 2. Then, the same film forming process as described above is carried out to form a high-K film 95 having a thickness of about several nanometers (nm) on the surface of the wafer W in the same manner, and after the high-K film 95 is formed, the wafer W is unloaded from the processing chamber 100. By performing the above film forming process a predetermined number of times, the deposited film 96 made of the high-K film corresponding to the cleaning target accumulates on regions other than the recessed portions 24 of the susceptor 2. For example, a cleaning process for removing the deposited film 96 from the susceptor 2 may be executed when the film thickness of the deposited film 96 reaches approximately 20 μm.

In the cleaning process, a crack generation step for generating cracks in the deposited film 96 is executed (step S304). Specifically, the processing chamber 100 that has been set to a vacuum atmosphere during the film forming process is opened to the atmosphere to be placed under an atmospheric pressure atmosphere, and the temperature of the processing chamber 100 that was raised to a high temperature by the heater unit 7 is set to room temperature. In this way, a large number of cracks 97 penetrating through the deposited film 96 from its outer surface to the inner surface facing the susceptor 2 are automatically generated in the deposited film 96 made of the high-K film.

After the cracks 97 penetrating through the deposited film 96 have been generated, the susceptor 2 is rotated once again, N₂ gas as the separation gas is supplied from the separation gas nozzles 41 and 42 into the processing chamber 100, and a fluorine-based gas, such as ClF₃, as a cleaning gas for removing the pre-coating film is supplied from the cleaning gas nozzle 35 to the susceptor 2. The fluorine-based gas supplied to the susceptor 2 permeates through the deposited film 96 through the cracks 97 and reaches the susceptor 2. Although the pre-coating film 90 is formed on the surface of the susceptor 2, because the pre-coating film 90 has a higher etch rate in the fluorine-based gas as compared with the etch rate of the deposited film 96, the pre-coating film 90 is etched by the fluorine-based gas, gasified, and dissipated (step S306: pre-coating film removing step).

In the pre-coating film removing step, while the pre-coating film 90 is etched by the fluorine-based gas, the susceptor 2, which is made of quartz or the like, is effectively prevented from being etched by the fluorine-based gas.

After the pre-coating film 90 is removed by the pre-coating film removing step, the deposited film removing step is executed (step S308). The deposited film removing step refers to a step of completely removing the deposited film 96 from the surface of the susceptor 2. However, in practice, the deposited film 96 may be lifted off from the susceptor 2 as a result of the dissipation of the pre-coating film 90. Accordingly, in the case where removal of the deposited film 96 can be deemed completed after the deposited film 96 is lifted off from the surface of the susceptor 2, the deposited film removing step may be automatically terminated upon completion of the pre-coating film removing step. In this case, the susceptor cleaning method according to the first embodiment ends when the pre-coating film removing step ends. Note that the above susceptor cleaning method is based on the dry cleaning method.

However, when the deposited film 96 is lifted off, residual strands of the deposited film 96 formed by the generation of the cracks 97 may remain on the surface of the susceptor 2. When the deposited film 96 is still present, the surface of the susceptor 2 cannot be deemed to have been completely cleaned. Accordingly, in the deposited film removing step, the interior of the processing chamber 100 is opened to the atmosphere, and a vacuum cleaner 98 is used to remove the deposited film 96 through vacuum suction.

When it can be determined that the deposited film 96 has been completely removed as a result of using the vacuum cleaner 98 to remove the deposited film 96 by vacuum suction, the deposited film removing step ends when the vacuum suction removal process is completed, and the susceptor cleaning method according to the first embodiment ends at this point.

On the other hand, at the time the vacuum suction removal process using the vacuum cleaner 98 has been completed, traces of the deposited film 96 may still remain adhered to the surface of the susceptor 2 without being lifted off from the susceptor 2. When the susceptor 2 having such traces of the deposited film 96 remaining thereon is reused, the traces of the deposited film 96 may cause the generation of particles. Thus, as a finishing process of the deposited film removing step, a wet cleaning process that involves removing the susceptor 2 from the processing chamber 100 and immersing the susceptor 2 with a cleaning solution 99 may be executed.

In the case where the deposited film 96 is made of a high-K film as described above, for example, a hydrofluoric acid solution (HF), a dilute hydrofluoric acid solution (DHF), a buffered hydrofluoric acid solution (BHF, NH₄/HF/H₂O), and the like may be used as the cleaning solution 99, and in this way, the high-K film can be dissolved in these cleaning solutions 99 and effectively removed from the surface of the susceptor 2.

Note that because most of the deposited film 96 is lifted off from the surface of the susceptor 2 in the previous processes of the deposited film removing step, the processing time of the wet cleaning process may be relatively short. In this way, the susceptor 2 may be prevented from being etched by DHF or the like in the wet cleaning process. Note that when there is not much residue of the deposited film 96 to be removed in the wet cleaning process, pure water may be used in the wet cleaning process, for example.

As described above, in the susceptor cleaning method according to the first embodiment, the susceptor 2 made of quartz or the like may be prevented from being etched by a fluorine-based gas or being etched by a cleaning solution such as DHF. In this way, the number of times the susceptor 2 can be reused may be increased and the service life of the susceptor 2 may be prolonged while periodically cleaning (maintaining) the susceptor 2.

### Susceptor Cleaning Method According to Second Embodiment

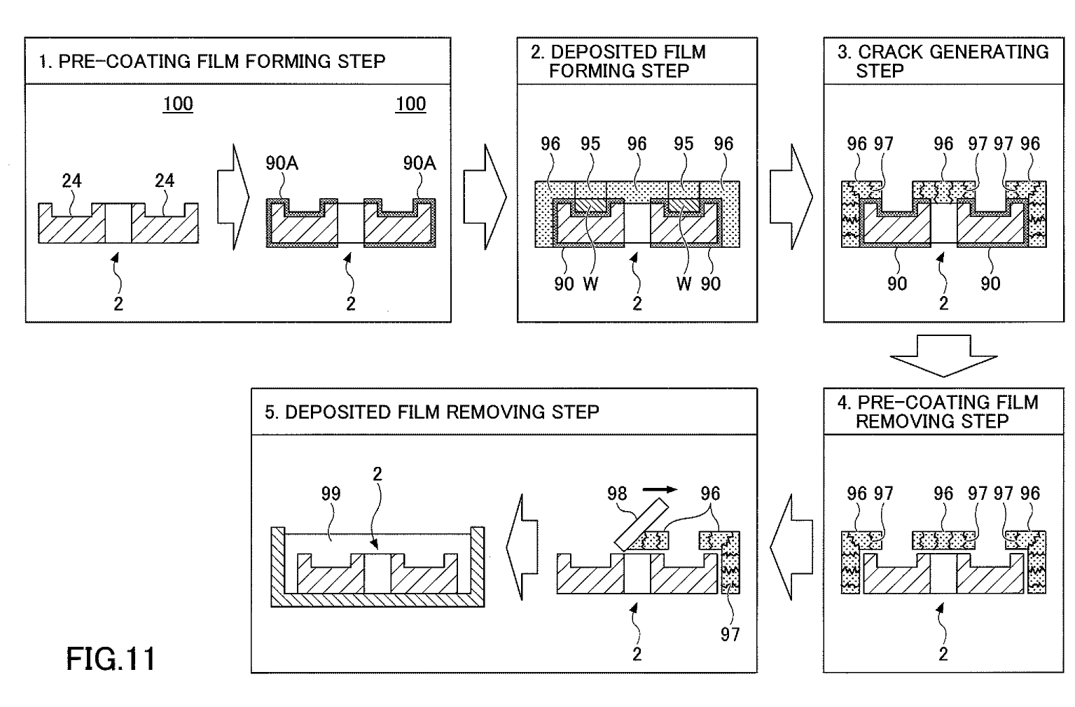

In the following, a susceptor cleaning method according to a second embodiment of the present invention will be described with reference to FIGS. 9 and 11. FIG. 11 is a diagram schematically illustrating the process flow of the susceptor cleaning method according to the second embodiment.

The differences between the susceptor cleaning method according to the first embodiment and the susceptor cleaning method according to the second embodiment lie in the type of film that is formed as the pre-coating film in the pre-coating film forming step and the type of reaction gas that is used in the pre-coating film removing step due to the difference in the film type of the pre-coating film. In the susceptor cleaning method according to the first embodiment, the pre-coating film is etched based on the differences in the etch rates of the pre-coating film and the deposited film (film formed by film forming process). In susceptor cleaning method according to the second embodiment, the pre-coating film is oxidized and removed by ashing. Note that in the following description of the susceptor cleaning method according to the second embodiment, explanations of process steps that are substantially the same as those implemented in the susceptor cleaning method according to the first embodiment will be omitted.

In the pre-coating film forming step according to the second embodiment, after placing the susceptor 2 in the processing chamber 100, the susceptor 2 is heated and rotated, N₂ gas as the separation gas is supplied from the separation gas nozzles 41 and 42, and a carbon-based gas as the pre-coating gas is supplied from the pre-coating gas nozzle 36. Because the susceptor 2 is heated and the interior of the processing chamber 100 is in a high-temperature atmosphere, chemical vapor deposition (CVD) of the carbon-based gas occurs and a pre-coating film 90A made of a CVD-carbon-based film is formed on the surface of the susceptor 2. Note that although the illustrated example shows a method of forming a CVD film by thermal energy, in other examples, a radio frequency power source may be provided in the processing chamber 100 and a method of forming a plasma CVD film by plasma energy may be implemented to form the pre-coating film.

In the deposited film forming step, a high-K film 95 is formed on a wafer W and a deposited film 96 is formed on the surface of the susceptor 2. At the stage where the deposited film 96 that has been formed on the surface of the susceptor 2 reaches a predetermined thickness, the crack generating step is executed to generate cracks 97 in the deposited film 96.

In the pre-coating film removing step of the susceptor cleaning method according to the present embodiment, an oxidizing gas, such as O₃ gas, as a pre-coating film removing gas is supplied from the oxidizing gas nozzle 32 to the susceptor 2.

The oxidizing gas that penetrates through the deposited film 96 through the cracks 97 and reaches the pre-coating film 90A made of the CVD-carbon-based film promotes ashing of the CVD-carbon-based film. Note that oxygen gas may also be used as the pre-coating film removing gas, and in the case where oxygen gas is used, the CVD-carbon-based film may be subjected to plasma ashing using oxygen gas that has been subjected to a plasma process.

By causing ashing of the pre-coating film 90A made of the CVD-carbon-based film using the oxidizing gas, the deposited film 96 may be lifted off from the surface of the susceptor 2. As with the susceptor cleaning method according to the first embodiment, after the deposited film 96 has been lifted off from the surface of the susceptor 2, residues of the deposited film 96 remaining on the susceptor 2 may be removed by vacuum suction as necessary, and the susceptor 2 may further be subjected to a wet cleaning process using a cleaning solution as necessary.

The susceptor cleaning method according to the second embodiment can similarly prevent the susceptor 2 made of quartz or the like from being etched by the fluorine-based gas or being etched by a cleaning solution such as DHF. In this way, the number of times the susceptor 2 is reused may be increased and the service life of the susceptor 2 may be prolonged while periodically cleaning (maintaining) the susceptor 2.

### Susceptor Cleaning Method According to Other Embodiment

Although not shown in the drawings, a susceptor cleaning method according to still another embodiment will be described below.

First, in the cleaning method according to the first and second embodiments, the processing chamber 100 that is used in the film forming process is used to form the pre-coating film on the surface of the susceptor 2. However, in a susceptor cleaning method according to another embodiment, a processing chamber that is different from the processing chamber 100 that is used in the film forming process may be used to form a pre-coating film on the surface of the susceptor 2. After the pre-coating film has been formed on the susceptor 2 in a different processing chamber, the susceptor 2 having the pre-coating film formed thereon may be accommodated in the processing chamber 100 that is used in the film forming process, and the subsequent process steps including the deposited film forming step, the crack generating step and the like as described above may executed in the processing chamber 100.

Although the present invention has been described above with respect to illustrative embodiments, the present invention is not limited to these embodiments and various variations and modifications may be made without departing from the scope of the present invention. For example, features and configurations described in connection with the above-described embodiments of the present invention may be combined to the extent practicable, and the present invention is not limited to the features and configurations of the above-described embodiments.

What is claimed is:

1. A susceptor cleaning method for cleaning a susceptor in a processing chamber, the susceptor cleaning method comprising:
a pre-coating film forming step of placing the susceptor in the processing chamber and forming a pre-coating film on a surface of the susceptor;
a deposited film forming step of placing a substrate on the susceptor having the pre-coating film formed thereon and performing a film forming process in the course of which a deposited film is formed on the susceptor;
a crack generating step of generating cracks in the deposited film;
a pre-coating film removing step of supplying a pre-coating film removing gas into the processing chamber, causing the pre-coating film removing gas to reach the pre-coating film through the cracks, and removing the pre-coating film; and
a deposited film removing step of removing the deposited film.

2. The susceptor cleaning method according to claim 1, wherein
the pre-coating film that is formed in the pre-coating film forming step has a higher etch rate than an etch rate of the deposited film; and
the pre-coating film removing step includes etching the pre-coating film using the pre-coating film removing gas.

3. The susceptor cleaning method according to claim 2, wherein
the pre-coating film is made of a SiO₂ film or a SiN film; and
the deposited film is made of a high-K film.

4. The susceptor cleaning method according to claim 3, wherein the pre-coating film removing gas is a cleaning gas made of a fluorine-based gas.

5. The susceptor cleaning method according to claim 4, wherein the cleaning gas is ClF₃ gas.

6. The susceptor cleaning method according to claim 1, wherein
the pre-coating film is made of a carbon-based film;
the pre-coating film removing gas is made of ozone or oxygen; and
the pre-coating film removing step includes ashing the pre-coating film using the pre-coating film removing gas.

7. The susceptor cleaning method according to claim 6, wherein
the pre-coating film is made of a carbon-based film; and
the deposited film is made of a high-K film.

8. The susceptor cleaning method according to claim 1, wherein
the deposited film forming step is performed by setting an internal atmosphere of the processing chamber to a vacuum atmosphere; and
the crack generating step is performed by setting the internal atmosphere of the processing chamber to an atmospheric pressure atmosphere to generate the cracks in the deposited film.

9. The susceptor cleaning method according to claim 1, wherein
in the deposited film removing step, the deposited film is lifted off from the susceptor as a result of the pre-coating film being removed in the pre-coating film removing step.

10. The susceptor cleaning method according to claim 9, wherein
in the deposited film removing step, residues of the deposited film remaining without being lifted off are further removed by a vacuum suction removal process.

11. The susceptor cleaning method according to claim 10, wherein
in the deposited film removing step, a cleaning process is performed after the vacuum suction removal process.

12. The susceptor cleaning method according to claim 11, wherein
a hydrofluoric acid solution (HF), a dilute hydrofluoric acid solution (DHF), a buffered hydrofluoric acid solution (BHF, NH₄/HF/H₂O), or pure water is used in the cleaning process.
